(19) United States
(12) Patent Application Publication
(10) Pub. No.: US 2025/0130262 A1
(43) Pub. Date: Apr. 24, 2025

(54) SINGLE-CHANNEL TEST DEVICE, TEST SYSTEM AND TEST METHOD THEREOF

(71) Applicants: Beijing BOE Sensor Technology Co., Ltd., Beijing (CN); BOE Technology Group Co., Ltd., Beijing (CN)

(72) Inventors: Liangrong GE, Beijing (CN); Sheng CHEN, Beijing (CN); Meng WEI, Beijing (CN); Yuanlong YANG, Beijing (CN); Zhifeng ZHANG, Beijing (CN); Chuncheng CHE, Beijing (CN); Yuanfu LI, Beijing (CN); Xueyan SU, Beijing (CN); Yunzhang ZHAO, Beijing (CN); Feng QU, Beijing (CN); Xiaoyong WANG, Beijing (CN); Xiaobo WANG, Beijing (CN)

(21) Appl. No.: 18/685,713

(22) PCT Filed: Sep. 20, 2022
(86) PCT No.: PCT/CN2022/120044

§ 371 Date: Feb. 22, 2024

(51) Int. Cl. G01R 29/08; G01R 29/10

(52) U.S. Cl. CPC G01R 29/0878; G01R 29/10

(57) ABSTRACT

The present disclosure provides a single-channel test device. The single-channel test device includes a metal flange, and a waveguide-coaxial conversion structure and a first square straight waveguide which are disposed along a central axis of the metal flange and disposed on two opposite sides of the metal flange respectively, wherein in the case that a waveguide aperture of one end of the first square straight waveguide distal to the metal flange is placed on and is kept in close contact with a single antenna unit to be tested in a phased reflectarray to be tested, the single-channel test device is configured to test a scattering parameter of the antenna unit to be tested.

The present disclosure is a U.S. national stage of international application No. PCT/CN2022/120044, filed on Sep. 20, 2022, the disclosure of which is herein incorporated by reference in its entirety.

### TECHNICAL FIELD

The present disclosure relates to the field of communication technologies, and particularly relates to a single-channel test device, a test system, and a test method thereof.

### BACKGROUND

In the fields of satellite communication, ground base station communication, etc., antennas are required to have a relatively high gain due to the long transmission distance and high transmission loss of wireless signals, and reflectarray antennas, as high-gain antennas, are widely used. Liquid crystal phased reflectarrays adopt liquid crystal as a functional electrically controlled phase-modulation material and thereby achieve large-angle beam scanning. In actual practice, accurate extraction of voltage-phase characteristic curves of various channel units is an important link in the calibration test of the liquid crystal phased reflectarrays, which provides a powerful guarantee for improving the phase-matching accuracy of the various channel units of the liquid crystal phased reflectarrays.

### SUMMARY

The present disclosure provides a single-channel test device, a test system, and a test method thereof.

Embodiments of the present disclosure provide a single-channel test device. The single-channel test device includes:

a metal flange, and a waveguide-coaxial conversion structure and a first square straight waveguide which are disposed along a central axis of the metal flange and disposed on two opposite sides of the metal flange respectively, wherein in the case that a waveguide aperture of one end of the first square straight waveguide distal to the metal flange is placed on and is kept in close contact with a single antenna unit to be tested in a phased reflectarray to be tested, the single-channel test device is configured to test a scattering parameter of the antenna unit to be tested.

In some embodiments of the present disclosure, the waveguide-coaxial conversion structure includes a second square straight waveguide extending along an extending direction which is the same as that of the first square straight waveguide, wherein the first square straight waveguide and the second square straight waveguide are both integrally formed with the metal flange, and the first square straight waveguide and the second square straight waveguide each include a cavity structure extending along the central axis.

In some embodiments of the present disclosure, the waveguide-coaxial conversion structure includes at least one SMA connector disposed at one end of the second square straight waveguide distal to the metal flange, and the waveguide-coaxial conversion structure is configured to convert a radio frequency (RF) signal received by the at least one SMA connector to an electromagnetic wave signal.

In some embodiments of the present disclosure, the single-channel test device includes a first polarization direction and a second polarization direction intersecting with the first polarization direction, wherein the at least one SMA connector includes a first SMA connector disposed in the first polarization direction and a second SMA connector disposed in the second polarization direction, and the distance between the first SMA connector and the metal flange is smaller than the distance between the second SMA connector and the metal flange.

In some embodiments of the present disclosure, the waveguide-coaxial conversion structure further includes an isolator disposed between the first SMA connector and the second SMA connector, wherein the isolator extends in the same direction as the first polarization direction, and runs through the cavity structure of the second square straight waveguide, and the isolator is configured to isolate an electromagnetic wave signal corresponding to the first SMA connector and an electromagnetic wave signal corresponding to the second SMA connector.

In some embodiments of the present disclosure, the isolator is a cylindrical probe having a bottom surface diameter of 0.6 mm and a length of 15.6 mm.

In some embodiments of the present disclosure, the at least one SMA connector only includes a third SMA connector, wherein the third SMA connector is disposed at one end of the second square straight waveguide distal to the metal flange along a third polarization direction of the single-channel test device.

In some embodiments of the present disclosure, sections of the first square straight waveguide and the second square straight waveguide along a direction intersecting with an extending direction of the central axis are square.

In some embodiments of the present disclosure, a side length of an inner wall of the first square straight waveguide and the second square straight waveguide ranges from 8 mm to 10 mm respectively.

In some embodiments of the present disclosure, a working frequency of the single-channel test device satisfies L₁=L₀×f₀/f₁, wherein L₀ represents that the side length of the inner wall of the first square straight waveguide and the second square straight waveguide is 9.6 mm, f₀ represents the working frequency in the case that the side length of the inner wall is 9.6 mm, and f₁ represents the working frequency in the case that the side length of the inner wall of the first square straight waveguide and the second square straight waveguide is L₁.

In some embodiments of the present disclosure, the metal flange is provided with at least one fixing hole in a through-thickness direction, wherein the at least one fixing hole is configured to be fixedly connected to a scanning frame.

Accordingly, embodiments of the present disclosure provide a test system. The test system includes:

the single-channel test device as described in any above embodiment, at least one RF cable and a vector network analyzer, wherein the single-channel test device is connected to the vector network analyzer through the at least one RF cable; the vector network analyzer is configured to extract a target scattering parameter from the scattering parameter based on a preset antenna type of the phased reflectarray to be tested, and draw a voltage-phase curve of the antenna unit to be tested based on the target scattering parameter.

In some embodiments of the present disclosure, the waveguide-coaxial conversion structure includes a second square straight waveguide extending along an extending direction which is the same as that of the first square straight waveguide, and at least one SMA connector disposed at one end of the second square straight waveguide distal to the metal flange; the first square straight waveguide and the second square straight waveguide are both integrally formed with the metal flange; the first square straight waveguide and the second square straight waveguide each include a cavity structure extending along the central axis; and the at least one SMA connector is connected to the at least one RF cable in a one-to-one correspondence manner.

In some embodiments of the present disclosure, the single-channel test device includes a first polarization direction and a second polarization direction intersecting with the first polarization direction; the at least one SMA connector includes a first SMA connector disposed in the first polarization direction and a second SMA connector disposed in the second polarization direction, and the distance between the first SMA connector and the metal flange is smaller than the distance between the second SMA connector and the metal flange; the at least one RF cable includes a first RF cable and a second RF cable; and the vector network analyzer includes a first port connected to the first SMA connector through the first RF cable, and a second port connected to the second SMA connector through the second RF cable.

In some embodiments of the present disclosure, the at least one SMA connector only includes a third SMA connector, wherein the third SMA connector is disposed at one end of the second square straight waveguide distal to the metal flange along a third polarization direction of the single-channel test device; the at least one RF cable only includes a third RF cable; and the third SMA connector is connected to the first port or the second port of the vector network analyzer through the third RF cable.

Accordingly, embodiments of the present disclosure provide a test method for any test system above. The test method includes:
the single-channel test device is placed on and kept in close contact with a reference metal substrate, and a reference scattering parameter of the single-channel test device is tested by the single-channel test device;
the single-channel test device is placed on and kept in close contact with the antenna unit to be tested in the phased reflectarray to be tested, a control voltage of the phased reflectarray to be tested is switched, and total scattering parameters of the single-channel test device and the antenna unit to be tested at each control voltage are tested by the single-channel test device;
the single-channel test device sends the reference scattering parameter and the total scattering parameter at each control voltage to the vector network analyzer; and
the vector network analyzer extracts the target scattering parameter of the antenna unit to be tested at each control voltage based on the preset antenna type of the phased reflectarray to be tested, the reference scattering parameter, and the total scattering parameter, and a voltage-phase curve of the antenna unit to be tested is drawn based on the target scattering parameter.

In some embodiments of the present disclosure, said extracting, by the vector network analyzer, the target scattering parameter of the antenna unit to be tested at each control voltage based on the preset antenna type of the phased reflectarray to be tested, the reference scattering parameter, and the total scattering parameter includes:
a calibrated scattering parameter of the antenna unit to be tested at each control voltage is acquired by subtracting the reference scattering parameter from the total scattering parameter at each control voltage through the vector network analyzer; and
the target scattering parameter of the antenna unit to be tested at each control voltage is extracted based on the preset antenna type and the calibrated scattering parameter.

In some embodiments of the present disclosure, in the case that the single-channel test device includes a first SMA connector coupled to a first port of the vector network analyzer and a second SMA connector coupled to a second port of the vector network analyzer, a polarization direction of the first SMA connector is a first polarization direction, and a polarization direction of the second SMA connector is a second polarization direction intersecting with the first polarization direction, the calibrated scattering parameter is calculated in the case that the control voltage is Vt by formula:

$${S}_{Vt}^{CAL} = [ \begin{matrix}{S}_{11}^{CAL} & {S}_{21}^{CAL} \\ {S}_{12}^{CAL} & {S}_{22}^{CAL}\end{matrix} ] = [ \begin{matrix}{S}_{11}^{ANT} & {S}_{21}^{ANT} \\ {S}_{12}^{ANT} & {S}_{22}^{ANT}\end{matrix} ] - [ \begin{matrix}{S}_{11}^{PEC} & {S}_{21}^{PEC} \\ {S}_{12}^{PEC} & {S}_{22}^{PEC}\end{matrix} ] = {S}_{Vt}^{ANT} - {S}^{PEC} ,$$

wherein S_{Vt}^{CAL} and

$$[ \begin{matrix}{S}_{11}^{CAL} & {S}_{21}^{CAL} \\ {S}_{12}^{CAL} & {S}_{22}^{CAL}\end{matrix} ]$$

represent the calibrated scattering parameter and a corresponding matrix respectively, S^{PEC} and

$$[ \begin{matrix}{S}_{11}^{PEC} & {S}_{21}^{PEC} \\ {S}_{12}^{PEC} & {S}_{22}^{PEC}\end{matrix} ]$$

represent the reference scattering parameter and a corresponding matrix respectively, S_{Vt}^{NT} and

$$[ \begin{matrix}{S}_{11}^{ANT} & {S}_{21}^{ANT} \\ {S}_{12}^{ANT} & {S}_{22}^{ANT}\end{matrix} ]$$

represent the total scattering parameter and a corresponding matrix respectively, S₁₁ and S₂₂ represent reflection coefficients, and S₂₁ and S₁₂ represent transmission coefficients.

In some embodiments of the present disclosure, the preset antenna type is a linear polarization type, and the target scattering parameter of the antenna unit to be tested in the case that the control voltage is Vt is acquired by the formula:

S_{Vt}^{X}=S₁₁^{CAL}, and S_{Vt}^{Y}=S₂₂^{CAL},

wherein S_{Vt}^{X} and S_{Vt}^{Y} represent the target scattering parameters.

In some embodiments of the present disclosure, the preset antenna type is a circular polarization type and the target scattering parameter of the antenna unit to be tested is acquired in the case that the control voltage is Vt by the formula:

$${S}_{Vt}^{RR} = [ ( {S}_{11}^{CAL} - {S}_{22}^{CAL} ) + j ( {S}_{12}^{CAL} + {S}_{21}^{CAL} ) ] / 2$$

$${S}_{Vt}^{LR} = [ ( {S}_{11}^{CAL} + {S}_{22}^{CAL} ) + j ( {S}_{12}^{CAL} - {S}_{21}^{CAL} ) ] / 2$$

$${S}_{Vt}^{RL} = [ ( {S}_{11}^{CAL} + {S}_{22}^{CAL} ) - j ( {S}_{12}^{CAL} - {S}_{21}^{CAL} ) ] / 2$$

$${S}_{Vt}^{LL} = [ ( {S}_{11}^{CAL} - {S}_{22}^{CAL} ) - j ( {S}_{12}^{CAL} + {S}_{21}^{CAL} ) ] / 2 ,$$

wherein the target scattering parameter includes at least one of S_{Vt}^{RR}, S_{Vt}^{LR}, S_{Vt}^{LL} and S_{Vt}^{RL}, S_{Vt}^{RR} represents a main polarization parameter of a right-handed circularly polarized antenna, S_{Vt}^{LR} represents a cross polarization parameter of the right-handed circularly polarized antenna, S_{Vt}^{LL} represents a main polarization parameter of a left-handed circularly polarized antenna and S_{Vt}^{RL} represents a cross polarization parameter of the left-handed circularly polarized antenna.

In some embodiments of the present disclosure, in the case that the single-channel test device includes a third SMA connector coupled to the first port of the vector network analyzer, and a polarization direction of the third SMA connector is a third polarization direction and the preset antenna type is a single linear polarization type, the target scattering parameter of the antenna unit to be tested in the case that the control voltage is Vt is calculated by formula:

$${S}_{Vt}^{CAL \_ Pol \_ 1} = {S}_{Vt}^{ANT \_ Pol - 1} - {S}^{PEC} ,$$

wherein S^{PEC} represents the reference scattering parameter, S_{Vt}^{ANT_Pol_1} represents the total scattering parameter in the case that the control voltage is Vt, and S_{Vt}^{CAL_Pol_1} represents the target scattering parameter in the case that the control voltage is Vt.

In some embodiments of the present disclosure, in the case that the single-channel test device includes a third SMA connector coupled to the first port of the vector network analyzer, and a polarization direction of the third SMA connector is a third polarization direction, and the preset antenna type is a dual linear polarization type including the third polarization direction and a fourth polarization direction intersecting with the third polarization direction, the target scattering parameter of the antenna unit to be tested is calculated by using the following formula in the case that the control voltage is Vt:

$${S}_{Vt}^{CAL \_ Pol \_ 1} = {S}_{Vt}^{ANT \_ Pol \_ 1} - {S}^{PEC} ,$$

$$and$$

$${S}_{Vt}^{CAL \_ Pol \_ 2} = {S}_{Vt}^{ANT \_ Pol \_ 2} - {S}^{PEC} ,$$

wherein S_{Vt}^{CAL_Pol_1} represents a first scattering sub-parameter extracted in the case that the third polarization direction of the single-channel test device is the same as the first polarization direction of the antenna unit to be tested, S_{Vt}^{CAL_Pol_2} represents a second scattering sub-parameter extracted in the case that the single-channel test device is rotated by 90° to keep the third polarization direction the same as the second polarization direction of the antenna unit to be tested, S_{Vt}^{CAL_Pol_1} represents the target scattering parameter in the first polarization direction in the case that the control voltage is Vt, and S_{Vt}^{ANT_Pol_2} represents the target scattering parameter in the second polarization direction in the case that the control voltage is Vt.

### BRIEF DESCRIPTION OF DRAWINGS

FIG. 1 is a structural schematic diagram of a single-channel test device according to some embodiments of the present disclosure;

FIG. 2 is a structural schematic diagram, viewed from above, corresponding to FIG. 1;

FIG. 3 is a structural block diagram of a test system according to some embodiments of the present disclosure;

FIG. 4 is a structural schematic diagram of a test system according to some embodiments of the present disclosure;

FIG. 5 is a structural schematic diagram of another test system according to some embodiments of the present disclosure;

FIG. 6 is a structural schematic diagram of still another test system according to some embodiments of the present disclosure;

FIG. 7 is a method flowchart of a test method for a test system according to some embodiments of the present disclosure;

FIG. 8 is a structural schematic diagram showing the placement of a single-channel test device and a reference metal substrate in the test method for the test system according to some embodiments of the present disclosure;

FIG. 9 is a structural schematic diagram showing the placement of the single-channel test device and a phased reflectarray to be tested in the test method for the test system according to some embodiments of the present disclosure;

FIG. 10 is a method flowchart of S104 in FIG. 7;

FIG. 11 is a flowchart of a method for drawing a voltage-phase curve of an antenna unit to be tested by taking the test system shown in FIG. 5 as an example;

FIG. 12 is a schematic diagram of a voltage-phase curve of an antenna unit to be tested, which is drawn by taking the test system shown in FIG. 5 as an example; and

FIG. 13 is a flowchart of a method for drawing a voltage-phase curve of an antenna unit to be tested by taking the test system shown in FIG. 6 as an example.

### DETAILED DESCRIPTION

For clearer descriptions of the objectives, technical solutions, and advantages of embodiments of the present disclosure, the technical solutions of the embodiments of the present disclosure are described clearly and completely hereinafter with reference to the accompanying drawings of the embodiments of the present disclosure. Obviously, the embodiments described here are only some but not all embodiments of the present disclosure. The embodiments and features in the embodiments of the present disclosure may be combined with one another under the condition of no conflict. All other embodiments derived by those of ordinary skill in the art based on the described embodiments of the present disclosure without creative efforts shall fall within the scope of protection of the present disclosure.

Unless defined otherwise, the technical terms or scientific terms used in the present disclosure should have the normal meaning understood by those of general skill in the art. The word “comprise” or “include” and similar terms used in the present disclosure mean that elements or objects appearing before the term cover the listed elements or objects and its equivalents appearing after the term while other elements or objects are not excluded.

It should be noted that the sizes and shapes of the accompanying drawings do not reflect the true proportions and the accompanying drawings are only intended to schematically illustrate the content of the present disclosure. The same or similar reference signs denote the same or similar elements or elements having the same or similar functions all the time.

In some practices, phase information of liquid crystal phased array units is extracted with dual-channel waveguides. Specifically, an experimental unit and a waveguide are integrated by designing experimental tooling, and the performance of the tested experimental unit is used to characterize the working characteristics of a tested antenna. However, this phase extraction method has the following problems. (1) Requirements for process consistency are extremely high; and once the processing process cannot bring initial phase consistency and phase shift consistency of the tested antennas to a certain level, the performance of the experimental unit cannot fully characterize the working characteristics of the tested antennas, which will negatively affect the phase-matching accuracy of the tested antennas greatly and thus cause performance degradation. It can be seen that this phase extraction method is only applicable to theoretical research rather than actual product design. (2) The antenna type of the tested antennas is limited; and the dual-channel waveguides are only applicable to the calibration of single linearly-polarized antennas instead of dual linearly-polarized antennas and circularly polarized antennas. In addition, this phase extraction method is also not applicable to the extraction of phase information of complex arrays. For example, antenna units of dual-polarized antenna arrays and receiving/transmitting shared-aperture antenna arrays are relatively complex, which excites relatively complex spatial fields during calibration test. Therefore, it is necessary to minimize mutual interference among the individual units to improve the purity of the phase information of the tested units. If multi-channels or multi-channel calibration test methods are used, mutual interference among antenna units cannot be avoided, resulting in relatively low test accuracy. For example again, for a rotation array, individual units rotate spatially and thus individual channel units greatly differ from one another in initial phase. If a dual-channel or multi-channel calibration test method is used, phases of the tested channels will be subjected to vector addition and cancel one another, which makes it impossible to extract the phase information of the channels at all, resulting in relatively low test accuracy.

In view of this, the embodiments of the present disclosure provide a single-channel test device, a test system, and a test method thereof for improving the phase-matching accuracy of phased reflectarrays.

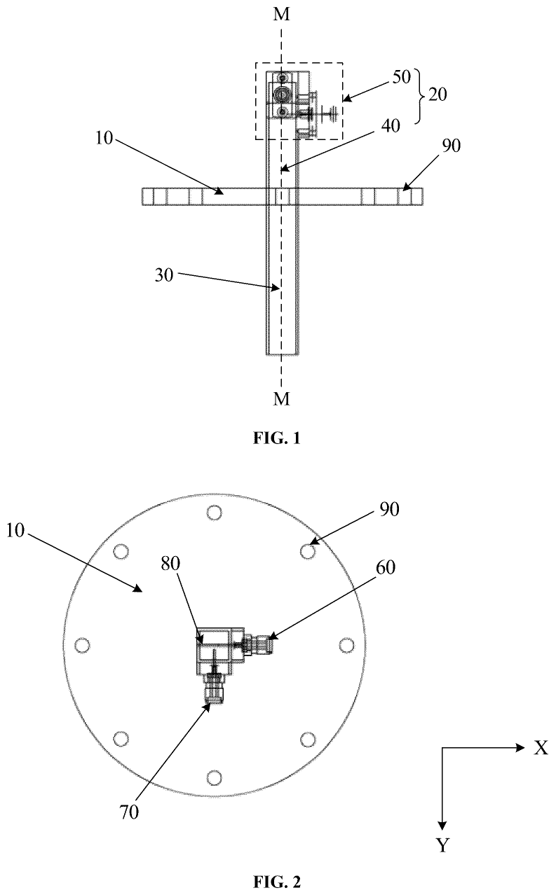

As shown in FIG. 1, the embodiments of the present disclosure provide a single-channel test device. The single-channel test device includes:

a metal flange 10, and a waveguide-coaxial conversion structure 20 and a first square straight waveguide 30 which are disposed along the central axis of the metal flange 10 and disposed on two opposite sides of the metal flange 10 respectively, wherein in the case that a waveguide aperture of one end of the first square straight waveguide 30 distal to the metal flange 10 is placed above a single antenna unit to be tested in a phased reflectarray to be tested and is kept in close contact with the single antenna unit to be tested, the single-channel test device is configured to test a scattering parameter of the antenna unit to be tested.

In some implementations, the single-channel test device provided by the embodiments of the present disclosure includes the metal flange 10, the waveguide-coaxial conversion structure 20 and the first square straight waveguide 30. The waveguide-coaxial conversion structure 20 and the first square straight waveguide 30 are disposed along the central axis of the metal flange 10 and disposed on two opposite sides of the metal flange 10 respectively. The central axis of the metal flange 10 is denoted by dashed line MM in FIG. 1. In some embodiments, the metal flange 10 is provided with fixing holes 90 in the periphery of a disc-shaped metal body and is connected to an object needing to be connected through these fixing holes 90.

In the case that the waveguide aperture of one end of the first square straight waveguide 30 distal to the metal flange 10 is placed above the single antenna unit to be tested in the phased reflectarray to be tested and close contact is maintained, the waveguide-coaxial conversion structure 20 is configured to convert a radio frequency (RF) signal received to an electromagnetic wave signal. The phased reflectarray to be tested includes a plurality of antenna units to be tested which is arranged in an array. Accordingly, the first square straight waveguide 30 is configured to transmit the electromagnetic wave signal to the antenna unit to be tested for excitation, and the electromagnetic wave signal, which has been subjected to phase modulation by the antenna unit to be tested, is then transmitted to the waveguide-coaxial conversion structure 20, so that the waveguide-coaxial conversion structure 20 converts the phase-modulated electromagnetic wave signal to the RF signal. Thus, in the embodiments of the present disclosure, by comparing and analyzing the RF signals corresponding to the electromagnetic wave signal before and after phase modulation by the antenna unit to be tested, the single-channel test device is configured to test the scattering parameter of the antenna unit to be tested. The scattering parameter may also be called the Scatter parameter, or S parameter. In some embodiments, the converted RF signal is transmitted to a vector network analyzer via a corresponding RF cable, so that the vector network analyzer acquires the scattering parameter of the antenna unit to be tested. Further, phase information of the antenna unit to be tested is extracted from the scattering parameter subsequently.

It should be noted that the phased reflectarray to be tested in the embodiments of the present disclosure is a liquid crystal phased array including a plurality of antenna units arranged in an array. Certainly, the material of a dielectric layer in the phased reflectarray to be tested is also selected according to actual needs, which is not limited here.

In the embodiments of the present disclosure, referring to FIG. 1 again, the waveguide-coaxial conversion structure 20 includes a second square straight waveguide 40 extending along an extending direction which is the same as that of the first square straight waveguide 30. The first square straight waveguide 30 and the second square straight waveguide 40 are both integrally formed with the metal flange 10, and the first square straight waveguide 30 and the second square straight waveguide 40 each include a cavity structure extending along the central axis.

Continue referring to FIG. 1, the waveguide-coaxial conversion structure 20 includes the second square straight waveguide 40 extending along the extending direction which is the same as that of the first square straight waveguide 30, and the first square straight waveguide 30 and the second square straight waveguide 40 are both integrally formed with the metal flange 10, so that the structural stability of the single-channel test device is ensured. In addition, as the first square straight waveguide 30 and the second square straight waveguide 40 each includes the cavity structure extending along the central axis of the metal flange 10, thereby ensuring the propagation performance of electromagnetic wave signals in the first square straight waveguide 30 and the second square straight waveguide 40. Accordingly, the first square straight waveguide 30 and the second square straight waveguide 40 each are of a cavity structure provided with an inner side wall and an outer side wall. In some implementations, the structure of the cavity structure is adjusted according to actual needs, thereby adjusting the test performance of the single-channel test device.

In the embodiments of the present disclosure, the waveguide-coaxial conversion structure 20 includes at least one SMA connector 50 disposed at one end of the second square straight waveguide 40 distal to the metal flange 10, and the waveguide-coaxial conversion structure 20 is configured to convert an RF signal received by the at least one SMA connector 50 to an electromagnetic wave signal.

In some implementations, the waveguide-coaxial conversion structure 20 includes at least one SMA connector 50 disposed at one end of the second square straight waveguide 40 distal to the metal flange 10. The number of the at least one SMA connector 50 is one or more, and the specific number of the at least one SMA connector 50 is set according to actual needs, which is not limited here. Accordingly, the waveguide-coaxial conversion structure 20 is configured to convert the RF signal received by the at least one SMA connector 50 to the electromagnetic wave signal, so that the electromagnetic wave signal is transmitted in the second square straight waveguide 40.

In some implementations, the waveguide-coaxial conversion structure 20 has, but is not limited to, the following setting modes. In some embodiments, referring to FIG. 1 and FIG. 2, FIG. 2 is a structural schematic diagram, viewed from above, of the single-channel test device shown in FIG. 1, and the single-channel test device includes a first polarization direction and a second polarization direction intersecting with the first polarization direction; the at least one SMA connector 50 includes a first SMA connector 60 disposed in the first polarization direction and a second SMA connector 70 disposed in the second polarization direction; and the distance between the first SMA connector 60 and the metal flange 10 is smaller than the distance between the second SMA connector 70 and the metal flange 10.

Referring to FIG. 2, the single-channel test device includes the first polarization direction and the second polarization direction intersecting with the first polarization direction, the first polarization direction is denoted by an arrow X in FIG. 2 and the second polarization direction is denoted by an arrow Y in FIG. 2. In the embodiments, the at least one SMA connector 50 includes the first SMA connector 60 disposed in the first polarization direction and the second SMA connector 70 disposed in the second polarization direction; the distance between the first SMA connector 60 and the metal flange 10 is smaller than the distance between the second SMA connector 70 and the metal flange 10, that is, the first SMA connector 60 is closer to the metal flange 10 than the second SMA connector 70 is; and the first SMA connector 60 and the second SMA connector 70 are disposed in different planes parallel to the plane in which the metal flange 10 is disposed, respectively. Thus, mutual interference between an RF signal received by the first SMA connector 60 and an RF signal received by the second SMA connector 70 is avoided, thereby ensuring the use performance of the waveguide-coaxial conversion structure 20.

In the embodiments of the present disclosure, referring to FIG. 1 and FIG. 2, the waveguide-coaxial conversion structure 20 further includes an isolator 80 disposed between the first SMA connector 60 and the second SMA connector 70. The isolator 80 extends in the same direction as the first polarization direction and runs through the cavity structure of the second square straight waveguide 40, and the isolator 80 is configured to isolate an electromagnetic wave signal corresponding to the first SMA connector 60 and an electromagnetic wave signal corresponding to the second SMA connector 70.

In some implementations, the waveguide-coaxial conversion structure 20 further includes the isolator 80 disposed between the first SMA connector 60 and the second SMA connector 70. In some embodiments, referring to FIG. 2 again, the isolator 80 extends in the same direction as the first polarization direction, and runs through the cavity structure of the second square straight waveguide 40. In some embodiments, the isolator 80 also extends in the same direction as the second polarization direction, and runs through the cavity structure of the second square straight waveguide 40. In addition, the isolator 80 is configured to isolate the electromagnetic wave signal corresponding to the first SMA connector 60 and the electromagnetic wave signal corresponding to the second SMA connector 70. Thus, the test performance of the single-channel test device is improved.

In some embodiments, the isolator 80 is a cylindrical probe having a bottom surface diameter of 0.6 mm and a length of 15.6 mm. The cylindrical probe extends from one side of the inner wall of the waveguide and is embedded into the inner wall of the other side. Certainly, relevant structural parameters of the isolator 80 are also set according to the isolation degree required by actual practice, which is not limited here.

It should be noted that in the embodiments shown in FIG. 1 and FIG. 2, the single-channel test device is a single-channel dual-polarization test device and measures all scattering parameters of corresponding components in two polarization directions, i.e., the first polarization direction and the second polarization direction. In the case that label “1” represents a feed port of the first SMA connector 60 and label “2” represents a feed port of the second SMA connector 70, the scattering parameters include reflection coefficients including S11 and S22, and transmission coefficients including S21 and S12. Specifically, S11 represents a reflection coefficient of the feed port of the first SMA connector 60, that is, an input reflection coefficient, i.e. input return loss; S22 represents a reflection coefficient of the feed port of the second SMA connector 70, that is, an output reflection coefficient, i.e., output return loss; S12 represents a reverse transmission coefficient from the feed port of the second SMA connector 70 to the feed port of the first SMA connector 60; and S21 represents a forward transmission coefficient from the feed port of the first SMA connector 60 to the feed port of the second SMA connector 70. By combining these four S coefficients in different forms, the phase information of antennas in any polarization form is acquired by analysis. In this way, phase extraction of the phased reflectarray in any polarization form is achieved by the single-channel dual-polarization test device.

In some embodiments, the at least one SMA connector 50 only includes a third SMA connector. The third SMA connector is disposed at one end of the second square straight waveguide 40 distal to the metal flange 10 along a third polarization direction of the test device.

In some implementations, the at least one SMA connector 50 in the waveguide-coaxial conversion structure 20 only includes one third SMA connector. The third SMA connector is disposed at one end of the second square straight waveguide 40 distal to the metal flange 10 along the third polarization direction of the single-channel test device. In some implementations, it may be that either of the two SMA connectors shown in FIG. 1 or FIG. 2 is removed and the remaining SMA connector is regarded as the third SMA connector. It should be noted that in the embodiments, the single-channel test device is a single-channel single-polarization test device, and thus accurate testing of the linearly-polarized phased reflectarray to be tested is ensured while the design complexity of the single-channel test device is simplified.

In the embodiments of the present disclosure, referring to FIG. 1 again, sections, along a direction perpendicular to the extending direction of the central axis, of the first square straight waveguide 30 and the second square straight waveguide 40 are square.

In the embodiments of the present disclosure, the side length of the inner wall in the first square straight waveguide 30 and the second square straight waveguide 40 ranges from 8 mm to 10 mm.

In some embodiments, the outer wall size of the first square straight waveguide 30 and the second square straight waveguide 40 is 11.6 mm*11.6 mm. The inner wall size of the first square straight waveguide 30 and the second square straight waveguide 40 is 9.6 mm*9.6 mm. The wall thickness of the first square straight waveguide 30 and the second square straight waveguide 40 is 1 mm. Certainly, the outer wall size, the inner wall size and the wall thickness of the first square straight waveguide 30 and the second square straight waveguide 40 are set according to actual needs, which is not limited here.

In the embodiments of the present disclosure, a working frequency of the single-channel test device satisfies L₁=L₀×f₀/f₁, wherein L₀ represents that the side length of the inner wall of the first square straight waveguide 30 and the second square straight waveguide 40 is 9.6 mm, f₀ represents the working frequency in the case that the side length of the inner wall is 9.6 mm, and f₁ represents the working frequency in the case that the side length of the inner wall of the first square straight waveguide 30 and the second square straight waveguide 40 is L₁.

In some implementations, the working frequency of the single-channel test device needs to meet L₁=L₀×f₀/f₁, wherein L₀ represents that the side length of the inner wall of the first square straight waveguide 30 and the second square straight waveguide 40 is 9.6 mm, f₀ represents the working frequency in the case that the side length of the inner wall is 9.6 mm, and f₁ represents working frequency in the case that the side length of the inner wall of the first square straight waveguide 30 and the second square straight waveguide 40 is L₁. In some embodiments, by taking that the phased reflectarray to be tested is a liquid crystal phased array as an example, the working frequency of the single-channel test device and the working frequency band range of the liquid crystal phased array ranges from 18 GHz to 21 GHz. Accordingly, the working wavelength of each SMA connector is 2.92 mm. In actual practice, the working frequency f0 of the single-channel test device is used as a reference frequency in the case that the side length of the inner wall of the first square straight waveguide 30 and the second square straight waveguide 40 is 9.6 mm; and subsequently, a specific value required for adjusting the side length of the inner wall of the first square straight waveguide 30 and the second square straight waveguide 40 based on L0 is determined according to a ratio relationship between the working frequency f1 required by the single-channel test device and f0. Thus, adjustment of a variety of working frequencies of the single-channel test device is achieved.

In the embodiments of the present disclosure, the metal flange 10 is provided with at least one fixing hole 90 along a through-thickness direction and the at least one fixing hole 90 is configured to be fixedly connected to a scanning frame.

In some implementations, referring to FIG. 1 and FIG. 2, the metal flange 10 is provided with at least one fixing hole 90 along a through-thickness direction, and the number of the at least one fixing hole 90 is one or more. Certainly, the specific number of the at least fixing hole 90 is set according to actual needs, which is not limited here. In some embodiments, the at least one fixing hole 90 may be configured to be fixedly connected to the scanning frame. By moving the scanning frame, the single-channel test device performs sequential scanning tests on the plurality of antenna units arranged in an array in the phased reflectarray to be tested, thereby improving the test performance of the single-channel test device.

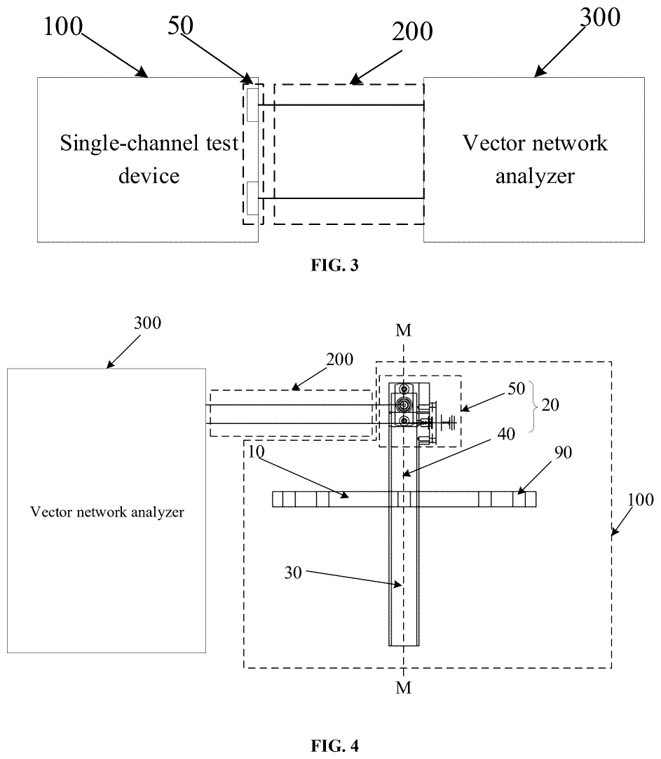

Based on the same concept, as shown in FIG. 3, the embodiments of the present disclosure further provide a test system. The test system includes:

any single-channel test device 100 above, at least one RF cable 200 and a vector network analyzer 300. The single-channel test device 100 is connected to the vector network analyzer 300 through the at least one RF cable 200; and the vector network analyzer 300 is configured to extract a target scattering parameter from the scattering parameters based on a preset antenna type of the phased reflectarray to be tested, and draw a voltage-phase curve of the antenna unit to be tested based on the target scattering parameter.

Referring to FIG. 3, the test system includes the single-channel test device 100, the at least one RF cable 200 and the vector network analyzer 300. The specific number of the at least one RF cable 200 is the same as the number of the SMA connectors to be connected. FIG. 3 shows the case that the number of the at least one RF cable 200 is two, but it is not limited to this. In some implementations, the single-channel test device 100 is connected to the vector network analyzer 300 through the at least one RF cable 200. The single-channel test device 100 is configured to test the scattering parameter of the single antenna unit to be tested in the phased reflectarray to be tested. The vector network analyzer 300 is configured to extract the target scattering parameter from the scattering parameters, tested by the single-channel test device 100, based on the preset antenna type of the phased reflectarray to be tested, and draw the voltage-phase curve of the antenna unit to be tested based on the target scattering parameter. The vector network analyzer 300 is a test device of electromagnetic wave energy, not only can measure various parameter amplitudes and phases of single-port or two-port networks, but also can display tested data using a Smith chart. The preset antenna type is a linear polarization type, such as a single linear-polarization or dual linear-polarization type; or a circular polarization type, such as single circular-polarization or dual circular-polarization type, which is not limited here.

In some implementations, the phase information of individual antenna units to be tested in the phased reflectarray to be tested may be independently extracted via the single-channel test device 100, thereby realizing precise phase-matching of single channel units, which is conductive to improving the working performance of the product and in line with high-quality product design concepts. In addition, the number of antenna units to be tested may be adjusted according to the consistency of an array processing technology. The higher the process consistency is, the fewer the number of tests is, and the higher the testing efficiency is, which is conductive to improving the test flexibility.

In the embodiments of the present disclosure, by taking the single-channel test device 100 shown in FIG. 1 as an example, FIG. 4 shows a structural schematic diagram of the test system. Accordingly, the waveguide-coaxial conversion structure 20 includes a second square straight waveguide 40 extending along an extending direction which is the same as that of the first square straight waveguide 30, and at least one SMA connector 50 disposed at one end of the second square straight waveguide 40 distal to the metal flange 10. The first square straight waveguide 30 and the second square straight waveguide 40 are both integrally formed with the metal flange 10; the first square straight waveguide 30 and the second square straight waveguide 40 each include a cavity structure extending along the central axis; and the at least one SMA connector 50 is connected to the at least one RF cable 200 in a one-to-one correspondence manner.

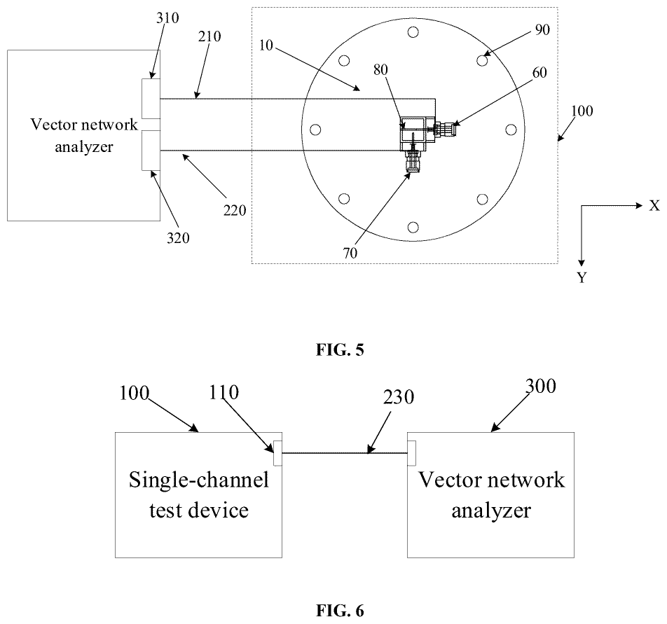

In the embodiments of the present disclosure, the test system may have, but is not limited to, the following setting modes according to the polarization type of the single-channel test device 100. In some embodiments, referring to FIG. 5, the single-channel test device 100 includes a first polarization direction and a second polarization direction intersecting with the first polarization direction; the at least one SMA connector 50 includes a first SMA connector 60 disposed in the first polarization direction and a second SMA connector 70 disposed in the second polarization direction, and the distance between the first SMA connector 60 and the metal flange 10 is smaller than the distance between the second SMA connector 70 and the metal flange 10; the at least one RF cable includes a first RF cable 210 and a second RF cable 220; and the vector network analyzer 300 includes a first port 310 connected to the first SMA connector 60 through the first RF cable 210, and a second port 320 connected to the second SMA connector 70 through the second RF cable 220.

Referring to FIG. 5, the single-channel test device 100 is a single-channel dual-polarization test device, and includes the first polarization direction and the second polarization direction intersecting with the first polarization direction. The at least one SMA connector 50 included in the waveguide-coaxial conversion structure 20 includes the first SMA connector 60 disposed in the first polarization direction and the second SMA connector 70 disposed in the second polarization direction. Moreover, the distance between the first SMA connector 60 and the metal flange 10 is smaller than the distance between the second SMA connector 70 and the metal flange 10. Accordingly, the at least one RF cable includes the first RF cable 210 and the second RF cable 220; and the vector network analyzer 300 includes the first port 310 connected to the first SMA connector 60 through the first RF cable 210, and the second port 320 connected to the second SMA connector 70 through the second RF cable 220. That is, the vector network analyzer 300 includes two ports, i.e., the first port 310 and the second port 320, and the single-channel test device 100 corresponding to the first SMA connector 60 is connected to the vector network analyzer 300 corresponding to the first port 310 through the first RF cable 210. In this way, the vector network analyzer 300 analyzes a reflection parameter extracted by the single-channel test device 100 in the first polarization direction. The single-channel test device 100 corresponding to the second SMA connector 70 is connected to the vector network analyzer 300 corresponding to the second port 320 through the second RF cable 220. In this way, the vector network analyzer 300 analyzes a reflection parameter extracted by the single-channel test device 100 in the second polarization direction. Thus, the phase extraction of the antenna unit to be tested in the first polarization direction and the second polarization direction is realized.

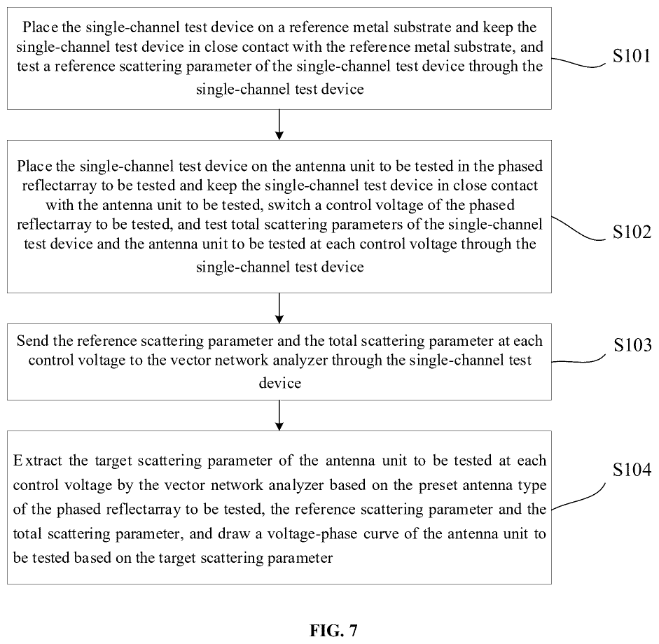

In some embodiments, as shown in FIG. 6, the at least one SMA connector 50 only includes a third SMA connector 110 and the third SMA connector 110 is disposed at one end of the second square straight waveguide 40 distal to the metal flange 10 along a third polarization direction of the single-channel test device 100; the at least one RF cable 200 only includes a third RF cable 230; and the third SMA connector 110 is connected to the first port 310 or the second port 320 of the vector network analyzer 300 through the third RF cable 230.

Referring to FIG. 6, the single-channel test device 100 is a single-channel single-polarization test device. The at least one SMA connector 50 included in the waveguide-coaxial conversion structure 20 only includes one third SMA connector 110. The third SMA connector 110 is disposed along the third polarization direction of the single-channel test device 100 and disposed at one end of the second square straight waveguide 40 distal to the metal flange 10. The third polarization direction is the same as either the first polarization direction or the second polarization direction. Accordingly, the at least one RF cable 200 only includes the third RF cable; accordingly, the third SMA connector 110 is connected to the first port 310 or the second port 320 of the vector network analyzer 300 through the third RF cable. In some embodiments, the vector network analyzer 300 includes two ports including the first port 310 and the second port 320, and the single-channel test device 100 corresponding to the third SMA connector 110 is connected to the vector network analyzer 300 corresponding to the first port 310 through the third RF cable. In this way, the vector network analyzer 300 analyzes a reflection parameter extracted by the single-channel test device 100 in the third polarization direction. Thus, the phase extraction of the antenna unit to be tested in the third polarization direction is realized.

In some implementations, as the single-channel test device 100 provided by the embodiments of the present disclosure only tests one antenna unit to be tested in the phased reflectarray every time, the high flexibility of single-channel testing is achieved. In actual practice, the single-channel test device 100 provided by the embodiments of the present disclosure is applicable to phase information extraction of complex arrays, such as dual-polarized antenna arrays, receiving/transmitting shared-aperture antenna arrays and rotation arrays. In addition, compared with multi-channel waveguide test devices, the single-channel test device 100 provided by the embodiments of the present disclosure can independently extract the phase information of each channel unit of the phased reflectarray, and has stronger advantages in terms of test accuracy and test flexibility.

It should be noted that the specific structure of the single-channel test device 100 in the test system may refer to detailed description of the related section above, and will not be repeated here. In addition, as the principle of the test system in solving problems is similar that of the single-channel test device 100 above, the implementation of this test system may refer to the implementation of the single-channel test device 100, and will not be repeated here.

Based on the same concept, as shown in FIG. 7, the embodiments of the present disclosure provide a test method for the test system above. The test method includes:
S101, placing the single-channel test device on a reference metal substrate and keeping the single-channel test device in close contact with the reference metal substrate, and testing a reference scattering parameter of the single-channel test device through the single-channel test device;
S102, placing the single-channel test device on the antenna unit to be tested in the phased reflectarray to be tested and keeping the single-channel test device in close contact with the antenna unit to be tested, switching a control voltage of the phased reflectarray to be tested, and testing, by the single-channel test device, total scattering parameters of the single-channel test device and the antenna unit to be tested at each control voltage;
S103, sending, by the single-channel test device, the reference scattering parameter and the total scattering parameter at each control voltage to the vector network analyzer; and
S104, extracting, by the vector network analyzer, the target scattering parameter of the antenna unit to be tested at each control voltage based on the preset antenna type of the phased reflectarray to be tested, the reference scattering parameter and the total scattering parameter, and drawing a voltage-phase curve of the antenna unit to be tested based on the target scattering parameter.

In some implementations, by taking the single-channel test device 100 shown in FIG. 1 as an example, the processes of steps S101 to S104 are as follows.

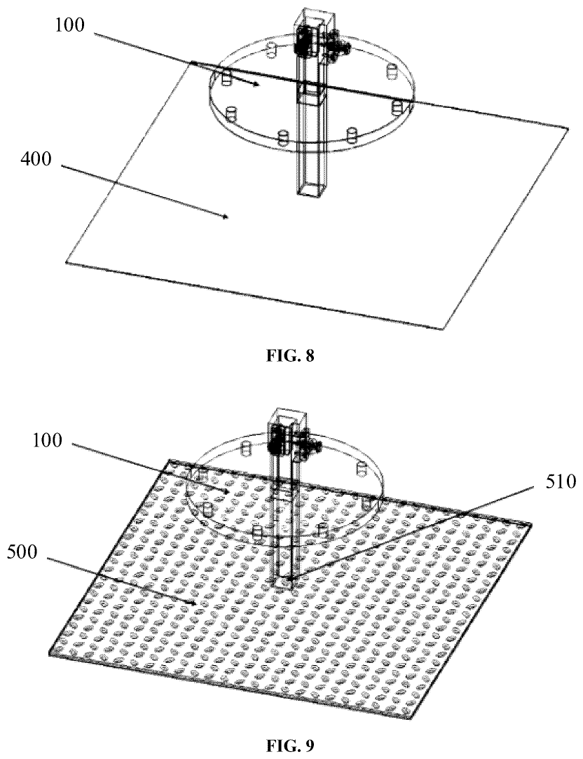

Firstly, the single-channel test device 100 is placed on the reference metal substrate 400 and the single-channel test device 100 is kept in close contact with the reference metal substrate 400, and the reference scattering parameter of the single-channel test device 100 is tested through the single-channel test device 100. In addition, the first SMA connector 60 on the waveguide-coaxial conversion structure 20 is connected to the first port 310 of the vector network analyzer 300 through the first RF cable 210. In some embodiments, the placement of the single-channel test device 100 and the reference metal substrate 400 is shown in FIG. 8. The reference metal substrate 400 is a copper substrate having a certain thickness, and certainly, the material of the reference metal substrate is also set according to actual needs, which is not limited here.

Then, the single-channel test device 100 is placed on the antenna unit to be tested 510 of the phased reflectarray to be tested 500 and the single-channel test device 100 is kept in close contact with the antenna unit to be tested 510. In some embodiments, the placement of the single-channel test device 100 and the phased reflectarray to be tested 500 is shown in FIG. 9. In addition, after the single-channel test device 100 is placed according to FIG. 9, the control voltage of the phased reflectarray to be tested 500 is switched. In this way, the total scattering parameter of the single-channel test device 100 and the antenna unit to be tested 510 at each control voltage is tested by the single-channel test device 100. For example, the control voltage of the phased reflectarray to be tested 500 is switched to V0-Vn, and the corresponding antenna unit 510 undergoes phase shift. Accordingly, the total scattering parameters of the single-channel test device 100 and the antenna unit to be tested 510 at each control voltage are acquired through the single-channel test device 100.

Then, the reference scattering parameter and the total scattering parameter at each control voltage are sent to the vector network analyzer 300 by the single-channel test device 100. After receiving the reference scattering parameter and the total scattering parameter at each control voltage, the vector network analyzer 300 extracts the target scattering parameter of the antenna unit to be tested 510 at the corresponding control voltage based on the preset antenna type of the phased reflectarray to be tested 500. In this way, the vector network analyzer 300 also extracts a corresponding phase based on the target scattering parameter, thus acquires a corresponding relationship between each control voltage and the corresponding phase of the antenna unit to be tested 510, and then draws a voltage-phase curve of the antenna unit to be tested 510. Thus, the phase test of the antenna unit to be tested 510 in the phased reflectarray to be tested 500 is achieved through the single-channel test device 100 and the vector network analyzer 300, thereby ensuring the corresponding phase-matching accuracy.

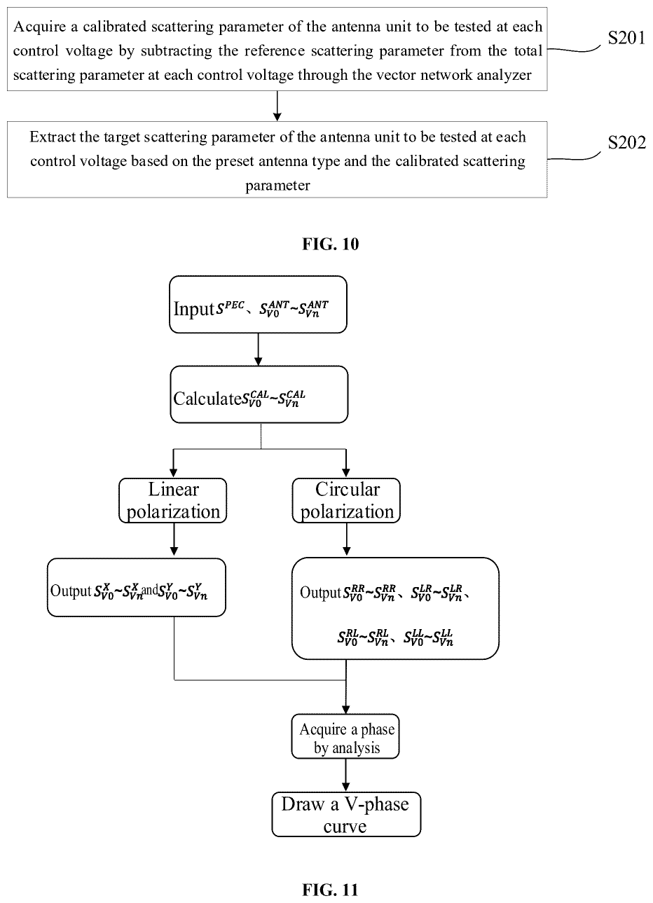

In the embodiments of the present disclosure, as shown in FIG. 10, step S104: extracting the target scattering parameter of the antenna unit to be tested at each control voltage by the vector network analyzer based on the preset antenna type of the phased reflectarray to be tested, the reference scattering parameter and the total scattering parameter includes:
S201, acquiring a calibrated scattering parameter of the antenna unit to be tested at each control voltage by subtracting the reference scattering parameter from the total scattering parameter at each control voltage through the vector network analyzer; and
S202, extracting the target scattering parameter of the antenna unit to be tested at each control voltage based on the preset antenna type and the calibrated scattering parameter.

In some implementations, the processes of steps S201 and S201 are as follows.

Firstly, the calibrated scattering parameter of the antenna unit to be tested 510 at each control voltage is acquired by subtracting the reference scattering parameter from the total scattering parameter at each control voltage through the vector network analyzer 300. For example, if at the control voltage Vt, the total scattering parameter is S_{Vt}^{ANT} and the reference scattering parameter is SPEC, the calibrated scattering parameter S_{Vt}^{CAL} satisfies: S_{Vt}^{CAL}=S_{Vt}^{ANT}−S^{PEC}. After the calibrated scattering parameter of the antenna unit to be tested 510 at each control voltage is acquired, the target scattering parameter of the antenna unit to be tested 510 at each control voltage is extracted based on the preset antenna type and the calibrated scattering parameter. As there may be a variety of preset antenna types, the target scattering parameters of the antenna unit to be tested 510 extracted at the corresponding control voltage are also different. The extraction process of the target scattering parameter may refer to the description of the related section bellow and is not repeated here.

In some embodiments, by taking the test system shown in FIG. 5 as an example, if the single-channel test device 100 includes a first SMA connector 60 coupled to a first port 310 of the vector network analyzer 300 and a second SMA connector 70 coupled to a second port 320 of the vector network analyzer 300; a polarization direction of the first SMA connector 60 is the first polarization direction; and a polarization direction of the second SMA connector 70 is the second polarization direction intersecting with the first polarization direction, the calibrated scattering parameter is calculated in the case the control voltage is Vt by the following formula:

$${S}_{Vt}^{CAL} = [ \begin{matrix}{S}_{11}^{CAL} & {S}_{21}^{CAL} \\ {S}_{12}^{CAL} & {S}_{22}^{CAL}\end{matrix} ] = [ \begin{matrix}{S}_{11}^{ANT} & {S}_{21}^{ANT} \\ {S}_{12}^{ANT} & {S}_{22}^{ANT}\end{matrix} ] - [ \begin{matrix}{S}_{11}^{PEC} & {S}_{21}^{PEC} \\ {S}_{12}^{PEC} & {S}_{22}^{PEC}\end{matrix} ] = {S}_{Vt}^{ANT} - {S}^{PEC} ,$$

wherein S_{Vt}^{CAL} and

$$[ \begin{matrix}{S}_{11}^{CAL} & {S}_{21}^{CAL} \\ {S}_{12}^{CAL} & {S}_{22}^{CAL}\end{matrix} ]$$

represent the calibrated scattering parameter and a corresponding matrix respectively, S^{PEC} and

$$[ \begin{matrix}{S}_{11}^{PEC} & {S}_{21}^{PEC} \\ {S}_{12}^{PEC} & {S}_{22}^{PEC}\end{matrix} ]$$

represent the reference scattering parameter and a corresponding matrix respectively, S_{Vt}^{ANT} and

$$[ \begin{matrix}{S}_{11}^{ANT} & {S}_{21}^{ANT} \\ {S}_{12}^{ANT} & {S}_{22}^{ANT}\end{matrix} ]$$

represent the total scattering parameter and a corresponding matrix respectively, S₁₁ and S₂₂ represent reflection coefficients, and S₂₁ and S₁₂ represent transmission coefficients.

Referring to FIG. 5 again, in some embodiments, the preset antenna type is a linear polarization type, and the target scattering parameter of the antenna unit to be tested 510 is acquired in the case that the control voltage is Vt by the following formula:

S_{Vt}^{X}=S₁₁^{CAL}, and S_{Vt}^{Y}=S₂₂^{CAL},

wherein S_{Vt}^{X} and S_{Vt}^{Y} represent target scattering parameters.

In some embodiments, S_{Vt}^{X} and S_{Vt}^{Y} represent the scattering parameters of the antenna unit to be tested 510 in the first polarization direction (i.e., the X direction) and the second polarization direction (i.e., the Y direction) respectively. For the single linearly-polarized antenna, it only needs to extract the parameter in one polarization direction. For the dual linearly-polarized antenna, S_{Vt}^{X} and S_{Vt}^{Y} represent the scattering parameters in the two polarization directions. In some implementations, the control voltage Vt is set as V0-Vn sequentially, where n is a positive integer, and the acquired target scattering parameters include S_{V0}^{X}-S_{Vn}^{X} and S_{V0}^{X}-S_{Vn}^{Y}. It should be noted that in the embodiments of the present disclosure, unless otherwise specified, specific values of V0-Vn are set according to actual needs, which is not limited here. Referring to FIG. 5 again, in some embodiments, the preset antenna type is a circular polarization type and the target scattering parameter of the antenna unit to be tested 510 is acquired in the case that the control voltage is Vt by the following formula:

$${S}_{Vt}^{RR} = [ ( {S}_{11}^{CAL} - {S}_{22}^{CAL} ) + j ( {S}_{12}^{CAL} + {S}_{21}^{CAL} ) ] / 2$$

$${S}_{Vt}^{LR} = [ ( {S}_{11}^{CAL} + {S}_{22}^{CAL} ) + j ( {S}_{12}^{CAL} - {S}_{21}^{CAL} ) ] / 2$$

$${S}_{Vt}^{RL} = [ ( {S}_{11}^{CAL} + {S}_{22}^{CAL} ) - j ( {S}_{12}^{CAL} - {S}_{21}^{CAL} ) ] / 2$$

$${S}_{Vt}^{LL} = [ ( {S}_{11}^{CAL} - {S}_{22}^{CAL} ) - j ( {S}_{12}^{CAL} + {S}_{21}^{CAL} ) ] / 2 ,$$

wherein the target scattering parameter includes at least one of S_{Vt}^{RR}, S_{Vt}^{LR}, S_{Vt}^{LL} and S_{Vt}^{RL}, S_{Vt}^{RR} represents a main polarization parameter of a right-handed circularly polarized antenna, S_{Vt}^{LR} represents a cross polarization parameter of the right-handed circularly polarized antenna, S_{Vt}^{LL} represents a main polarization parameter of a left-handed circularly polarized antenna and S_{Vt}^{RL} represents a cross polarization parameter of the left-handed circularly polarized antenna.

In some embodiments, if the control voltage Vt is set as V0-Vn sequentially, where n is a positive integer, S_{V0}^{RR}-S_{Vn}^{RR}, S_{V0}^{LR}-S_{Vn}^{LR}, S_{V0}^{LL}-S_{Vn}^{LL} and S_{V0}^{RL}-S_{Vn}^{RL} may be acquired accordingly. In the case that the preset antenna type is a circular polarization type, the polarization mode of the antenna unit to be tested 510 is specifically one of a left-handed circular polarization mode, a right-handed circular polarization mode, and a dual circular polarization mode. In some implementations, corresponding calculation methods are selected based on the different polarization modes of the antenna unit to be tested 510, thereby extracting the corresponding scattering parameter. For example, if the polarization mode of the antenna unit to be tested 510 is the right-handed circular polarization mode, corresponding scattering parameters of S_{Vt}^{RR} and S_{Vt}^{LR} need to be extracted. For example again, if the polarization mode of the antenna unit to be tested 510 is the left-handed circular polarization mode, corresponding scattering parameters of S_{Vt}^{LL} and S_{Vt}^{RL} need to be extracted.

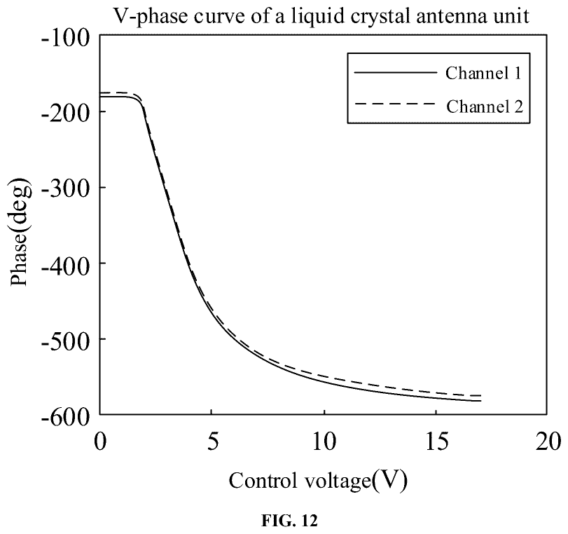

Accordingly, by taking the test system in FIG. 5 as an example, the control voltage is set as V0-Vn in sequentially, where n is a positive integer, and a flowchart of a method for drawing a voltage-phase (V-phase) curve of the antenna unit to be tested 510 by the vector network analyzer 300 based on the scattering parameter tested by the single-channel test device 100 and the preset antenna type is shown in FIG. 11. The corresponding total scattering parameters of the antenna unit to be tested 510 at the various control voltages are S_{V0}^{ANT}-S_{Vn}^{ANT} respectively; and the corresponding calibrated scattering parameters of the antenna unit to be tested 510 at the various control voltages are S_{V0}^{CAL}-S_{Vn}^{CAL} respectively. The process of each step in FIG. 11 may refer to the description of the related section above, and will not be repeated here. In some embodiments, by taking that the phased reflectarray to be tested may be a liquid crystal phased array including a plurality of antenna units arranged in an array as an example, for corresponding two liquid crystal units of channel 1 and channel 2, the drawn voltage-phase curves may be as shown in FIG. 12.

By taking the test system shown in FIG. 6 as an example, in the case that the single-channel test device includes a third SMA connector 310 coupled to the first port 310 of the vector network analyzer 300, and a polarization direction of the third SMA connector is a third polarization direction and the preset antenna is a single linear polarization type, such as one of a vertical polarization type, a horizontal polarization type, a +45° polarization type, and a −45° polarization type, the target scattering parameters of the antenna unit to be tested 510 in the case that the control voltage is Vt is calculated by the following formula:

$${S}_{Vt}^{CAL \_ Pol \_ 1} = {S}_{Vt}^{ANT \_ Pol \_ 1} - {S}^{PEC} ,$$

wherein S^{PEC} represents the reference scattering parameter, S_{Vt}^{ANT_Pol_1} represents the total scattering parameter in the case that the control voltage is Vt, and S_{Vt}^{CAL_Pol_1} represents the target scattering parameter in the case that the control voltage is Vt.

If the single-channel test device includes a third SMA connector 110 coupled to the first port 310 of the vector network analyzer 300, and a polarization direction of the third SMA connector is a third polarization direction and the preset antenna is a dual linear polarization type including the third polarization direction and a fourth polarization direction intersecting with the third polarization direction, such as one of a vertical dual linear polarization type, a horizontal dual linear polarization type, and ±45° dual linear polarization types, the target scattering parameters of the antenna unit to be tested 510 in the case that the control voltage is Vt are calculated by the following formulas:

$${S}_{Vt}^{CAL \_ Pol \_ 1} = {S}_{Vt}^{ANT \_ Pol \_ 1} - {S}^{PEC} ;$$

$$and$$

$${S}_{Vt}^{CAL \_ Pol \_ 2} = {S}_{Vt}^{ANT \_ Pol \_ 2} - {S}^{PEC} ,$$

where S_{Vt}^{CAL_Pol_1} represents a first scattering sub-parameter extracted in the case that the third polarization direction of the single-channel test device 100 is the same as the first polarization direction of the antenna unit to be tested 510, S_{Vt}^{CAL_Pol_2} represents a second scattering sub-parameter extracted in the case that the single-channel test device is rotated by 90° to keep the third polarization direction the same as the second polarization direction of the antenna unit to be tested 510, S_{Vt}^{CAL_Pol_1} represents the target scattering parameter in the first polarization direction in the case that the control voltage is Vt, and S_{Vt}^{ANT_Pol_2} represents the target scattering parameter in the second polarization direction in the case that the control voltage is Vt.

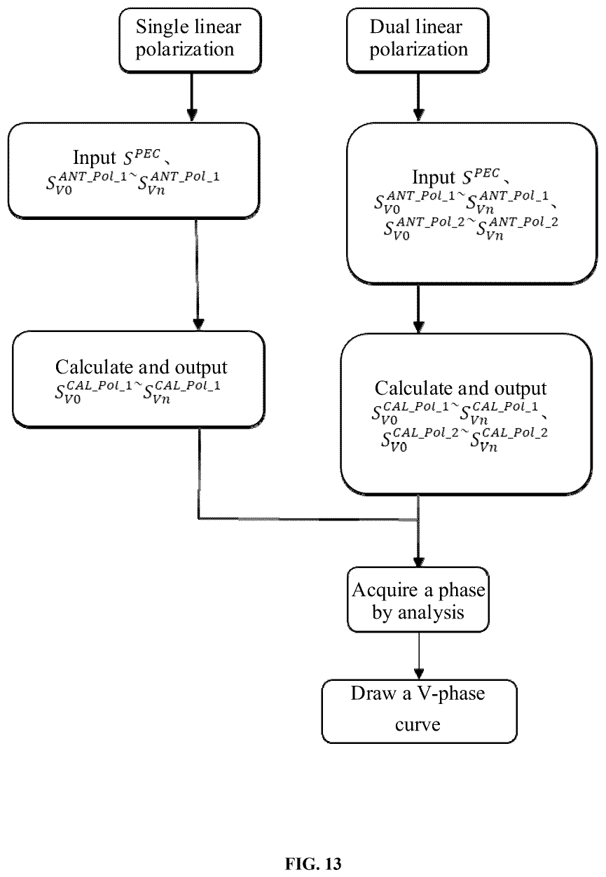

Accordingly, by taking the test system in FIG. 6 as an example, the control voltage is set as V0-Vn sequentially, where n is a positive integer, and a flowchart of a method for drawing a voltage-phase curve of the antenna unit to be tested 510 by the vector network analyzer 300 based on the scattering parameter tested by the single-channel test device 100 and the preset antenna type is shown in FIG. 13. In some embodiments, in the test system shown in FIG. 6, the vector network analyzer 300 is connected to the single-channel test device 100 through the first port 310. Under the condition that the antenna unit to be tested 510 is a single linearly-polarized antenna unit, the corresponding total scattering parameters of the antenna unit to be tested 510 at the various control voltages are S_{Vt}^{ANT_Pol_1}-S_{Vn}^{ANT_Pol_1}; and the corresponding calibrated scattering parameters of to the antenna unit to be tested 510 at the various control voltages are S_{V0}^{CAL_Pol_1}-S_{Vn}^{CAL_Pol_1}|. By still taking the test system shown in FIG. 6 as an example, under the condition that the antenna unit to be tested 510 is a dual linearly-polarized antenna unit, the single-channel test device 100 is firstly placed on the phased reflectarray to be tested 500 and is kept in close contact with the phased reflectarray to be tested 500, the polarization direction of the waveguide aperture and the polarization direction of the antenna unit to be tested are both the third polarization direction, and the first scattering sub-parameter S_{Vt}^{ANT-Pol_1} of the first port 310 of the vector network analyzer 300 is tested and extracted; then, the single-channel test device 100 is rotated by 90° and placed on the phased reflectarray to be tested 500 and is kept in close contact with the phased reflectarray to be tested 500, and the second scattering sub-parameter S_{Vt}^{ANT_Pol_2} is extracted using the same method. Accordingly, under the condition of dual linear polarization, the target scattering parameters of the antenna unit to be tested 510 are S_{Vt}^{CAL_Pol_1}=S_{Vt}^{ANT_Pol_1}−S^{PEC}; and S_{Vt}^{CAL_Pol_2}=S_{Vt}^{CAL_Pol_2}−S^{PEC}. It should be noted that in FIG. 13, the illustration is given by setting the control voltage as V0-Vn sequentially, where n is a positive integer. The process of each step in FIG. 13 refers to the description of the related section above, and will not be repeated here.

Although the embodiments of the present disclosure have been described, those skilled in the art may make additional changes and modifications to these embodiments once they have learned the basic creative concepts. Therefore, the attached claims are intended to be interpreted as including embodiments and all changes and modifications falling within the scope of the present disclosure.

Obviously, those skilled in the art may make various modifications and variations to the present disclosure without departing from the spirit and scope of the present disclosure. In this way, if these modifications and variations of the present disclosure fall within the scope of the claims and their equivalents, the present disclosure also intends to include these modifications and variations.

1. A single-channel test device, comprising:
a metal flange, and a waveguide-coaxial conversion structure and a first square straight waveguide which are disposed along a central axis of the metal flange and disposed on two opposite sides of the metal flange respectively, wherein in a case that a waveguide aperture of one end of the first square straight waveguide distal to the metal flange is placed on and is kept in close contact with a single antenna unit to be tested in a phased reflectarray to be tested, the single-channel test device is configured to test a scattering parameter of the antenna unit to be tested.

2. The single-channel test device according to claim 1, wherein the waveguide-coaxial conversion structure comprises a second square straight waveguide extending along an extending direction of the first square straight waveguide, wherein the first square straight waveguide and the second square straight waveguide are both integrally formed with the metal flange, and the first square straight waveguide and the second square straight waveguide each comprise a cavity structure extending along the central axis.

3. The single-channel test device according to claim 1, wherein the waveguide-coaxial conversion structure comprises at least one SMA connector disposed at one end of the second square straight waveguide distal to the metal flange, and the waveguide-coaxial conversion structure is configured to convert a radio frequency (RF) signal received by the at least one SMA connector to an electromagnetic wave signal.

4. The single-channel test device according to claim 3, comprising a first polarization direction and a second polarization direction intersecting with the first polarization direction, wherein the at least one SMA connector comprises a first SMA connector disposed in the first polarization direction and a second SMA connector disposed in the second polarization direction, and a distance between the first SMA connector and the metal flange is smaller than a distance between the second SMA connector and the metal flange.

5. The single-channel test device according to claim 4, wherein the waveguide-coaxial conversion structure further comprises an isolator disposed between the first SMA connector and the second SMA connector, wherein the isolator extends along the first polarization direction, and runs through the cavity structure of the second square straight waveguide, and the isolator is configured to isolate an electromagnetic wave signal corresponding to the first SMA connector and an electromagnetic wave signal corresponding to the second SMA connector.

6. The single-channel test device according to claim 3, wherein the at least one SMA connector only comprises a third SMA connector, wherein the third SMA connector is disposed at one end of the second square straight waveguide distal to the metal flange along a third polarization direction of the single-channel test device.

7. The single-channel test device according to claim 3, wherein sections of the first square straight waveguide and the second square straight waveguide along a direction perpendicular to an extending direction of the central axis are square.

8. The single-channel test device according to claim 7, wherein a side length of an inner wall of the first square straight waveguide and the second square straight waveguide ranges from 8 mm to 10 mm respectively.

9. The single-channel test device according to claim 8, wherein a working frequency of the single-channel test device satisfies L₁=L₀×f₀/f₁, wherein L₀ represents that the side length of the inner wall of the first square straight waveguide and the second square straight waveguide is 9.6 mm, f₀ represents the working frequency in a case that the side length of the inner wall is 9.6 mm, and f₁ represents the working frequency in a case that the side length of the inner wall of the first square straight waveguide and the second square straight waveguide is L₁.

10. (canceled)

11. A test system, comprising:
a single-channel test device, at least one radio frequency (RF) cable and a vector network analyzer, wherein the single-channel test device is connected to the vector network analyzer through the at least one RF cable;
the single-channel test device comprises a metal flange, and a waveguide-coaxial conversion structure and a first square straight waveguide which are disposed along a central axis of the metal flange and disposed on two opposite sides of the metal flange respectively, wherein in a case that a waveguide aperture of one end of the first square straight waveguide distal to the metal flange is placed on and is kept in close contact with a single antenna unit to be tested in a phased reflectarray to be tested, the single-channel test device is configured to test a scattering parameter of the antenna unit to be tested; and
the vector network analyzer is configured to extract a target scattering parameter from the scattering parameter based on a preset antenna type of the phased reflectarray to be tested, and draw a voltage-phase curve of the antenna unit to be tested based on the target scattering parameter.

12. The test system according to claim 11, wherein the waveguide-coaxial conversion structure comprises a second square straight waveguide extending along an extending direction of the first square straight waveguide, and at least one SMA connector disposed at one end of the second square straight waveguide distal to the metal flange; the first square straight waveguide and the second square straight waveguide are both integrally formed with the metal flange; the first square straight waveguide and the second square straight waveguide each comprise a cavity structure extending along the central axis; and the at least one SMA connector is connected to the at least one RF cable in a one-to-one correspondence manner.

13. The test system according to claim 12, wherein the single-channel test device comprises a first polarization direction and a second polarization direction intersecting with the first polarization direction; the at least one SMA connector comprises a first SMA connector disposed in the first polarization direction and a second SMA connector disposed in the second polarization direction, and a distance between the first SMA connector and the metal flange is smaller than a distance between the second SMA connector and the metal flange; the at least one RF cable comprises a first RF cable and a second RF cable; and the vector network analyzer comprises a first port connected to the first SMA connector through the first RF cable, and a second port connected to the second SMA connector through the second RF cable.

14. The test system according to claim 12, wherein the at least one SMA connector only comprises a third SMA connector, wherein the third SMA connector is disposed at one end of the second square straight waveguide distal to the metal flange along a third polarization direction of the single-channel test device; the at least one RF cable only comprises a third RF cable; and the third SMA connector is connected to the first port or the second port of the vector network analyzer through the third RF cable.

15. A test method for the test system according to claim 11, comprising:
placing the single-channel test device on a reference metal substrate and keeping the single-channel test device in close contact with the reference metal substrate, and testing, by the single-channel test device, a reference scattering parameter of the single-channel test device;
placing the single-channel test device on the antenna unit to be tested in the phased reflectarray to be tested and keeping the single-channel test device in close contact with the antenna unit to be tested, switching a control voltage of the phased reflectarray to be tested, and testing, by the single-channel test device, total scattering parameters of the single-channel test device and the antenna unit to be tested at each control voltage;
sending, the single-channel test device, the reference scattering parameter and the total scattering parameter at each control voltage to the vector network analyzer; and
extracting, by the vector network analyzer, the target scattering parameter of the antenna unit to be tested at each control voltage based on the preset antenna type of the phased reflectarray to be tested, the reference scattering parameter, and the total scattering parameter, and drawing a voltage-phase curve of the antenna unit to be tested based on the target scattering parameter.

16. The test method according to claim 15, wherein said extracting, by the vector network analyzer, the target scattering parameter of the antenna unit to be tested at each control voltage based on the preset antenna type of the phased reflectarray to be tested, the reference scattering parameter, and the total scattering parameter comprises:
acquiring, by the vector network analyzer, a calibrated scattering parameter of the antenna unit to be tested at each control voltage by subtracting the reference scattering parameter from the total scattering parameter at each control voltage; and
extracting the target scattering parameter of the antenna unit to be tested at each control voltage based on the preset antenna type and the calibrated scattering parameter.

17. The test method according to 16, wherein in a case that the single-channel test device comprises a first SMA connector coupled to a first port of the vector network analyzer and a second SMA connector coupled to a second port of the vector network analyzer, a polarization direction of the first SMA connector is a first polarization direction, and a polarization direction of the second SMA connector is a second polarization direction intersecting with the first polarization direction, the calibrated scattering parameter in a case that the control voltage is Vt is calculated by formula:
$${S}_{Vt}^{CAL} = [ \begin{matrix}{S}_{11}^{CAL} & {S}_{21}^{CAL} \\ {S}_{12}^{CAL} & {S}_{22}^{CAL}\end{matrix} ] = [ \begin{matrix}{S}_{11}^{ANT} & {S}_{21}^{ANT} \\ {S}_{12}^{ANT} & {S}_{22}^{ANT}\end{matrix} ] - [ \begin{matrix}{S}_{11}^{PEC} & {S}_{21}^{PEC} \\ {S}_{12}^{PEC} & {S}_{22}^{PEC}\end{matrix} ] = {S}_{Vt}^{ANT} - {S}^{PEC} ,$$
wherein S_{Vt}^{CAL} and
$$[ \begin{matrix}{S}_{11}^{CAL} & {S}_{21}^{CAL} \\ {S}_{12}^{CAL} & {S}_{22}^{CAL}\end{matrix} ]$$
represent the calibrated scattering parameter and a corresponding matrix respectively, S^{PEC} and
$$[ \begin{matrix}{S}_{11}^{PEC} & {S}_{21}^{PEC} \\ {S}_{12}^{PEC} & {S}_{22}^{PEC}\end{matrix} ]$$
represent the reference scattering parameter and a corresponding matrix respectively, S_{Vt}^{ANT} and
$$[ \begin{matrix}{S}_{11}^{ANT} & {S}_{21}^{ANT} \\ {S}_{12}^{ANT} & {S}_{22}^{ANT}\end{matrix} ]$$
represent the total scattering parameter and a corresponding matrix respectively, S11 and S22 represent reflection coefficients, and S21 and S12 represent transmission coefficients.

18. The test method according to 17, wherein the preset antenna type is a linear polarization type, and the target scattering parameter of the antenna unit to be tested in a case that the control voltage is Vt is acquired by formula:
S_{Vt}^{X}=S₁₁^{CAL}, and S_{Vt}^{Y}=S₂₂^{CAL},
wherein S_{Vt}^{X} and S_{Vt}^{Y} represent the target scattering parameters.

19. The test method according to 17, wherein the preset antenna type is a circular polarization type and the target scattering parameter of the antenna unit to be tested in a case that the control voltage is Vt is acquired by formula:
$${S}_{Vt}^{RR} = [ ( {S}_{11}^{CAL} - {S}_{22}^{CAL} ) + j ( {S}_{12}^{CAL} + {S}_{21}^{CAL} ) ] / 2$$
$${S}_{Vt}^{LR} = [ ( {S}_{11}^{CAL} + {S}_{22}^{CAL} ) + j ( {S}_{12}^{CAL} - {S}_{21}^{CAL} ) ] / 2$$
$${S}_{Vt}^{RL} = [ ( {S}_{11}^{CAL} + {S}_{22}^{CAL} ) - j ( {S}_{12}^{CAL} - {S}_{21}^{CAL} ) ] / 2$$
$${S}_{Vt}^{LL} = [ ( {S}_{11}^{CAL} - {S}_{22}^{CAL} ) - j ( {S}_{12}^{CAL} + {S}_{21}^{CAL} ) ] / 2 ,$$
wherein the target scattering parameter comprises at least one of S_{Vt}^{RR}, S_{Vt}^{LR}, S_{Vt}^{LL} and S_{Vt}^{RL}, S_{Vt}^{RR} represents a main polarization parameter of a right-handed circularly polarized antenna, S_{Vt}^{RR} represents a cross polarization parameter of the right-handed circularly polarized antenna, S_{Vt}^{LL} represents a main polarization parameter of a left-handed circularly polarized antenna and S_{Vt}^{RL} represents a cross polarization parameter of the left-handed circularly polarized antenna.

20. The test method according to claim 16, wherein in a case that the single-channel test device comprises a third SMA connector coupled to the first port of the vector network analyzer, and a polarization direction of the third SMA connector is a third polarization direction and the preset antenna type is a single linear polarization type, the target scattering parameter of the antenna unit to be tested in a case that the control voltage is Vt is calculated by formula:
$${S}_{Vt}^{CAL \_ Pol \_ 1} = {S}_{Vt}^{ANT \_ Pol \_ 1} - {S}^{PEC} ,$$
wherein S^{PEC} represents the reference scattering parameter, S_{Vt}^{ANT_Pol_1} represents the total scattering parameter in the case that the control voltage is Vt, and S_{Vt}^{CAL_Pol_1} represents the target scattering parameter in the case that the control voltage is Vt.

21. The test method according to claim 16, wherein in a case that the single-channel test device comprises a third SMA connector coupled to the first port of the vector network analyzer, and a polarization direction of the third SMA connector is a third polarization direction, and the preset antenna type is a dual linear polarization type including the third polarization direction and a fourth polarization direction intersecting with the third polarization direction, the target scattering parameter of the antenna unit to be tested in a case that the control voltage is Vt is calculated by formula:
$${S}_{Vt}^{CAL \_ Pol \_ 1} = {S}_{Vt}^{ANT \_ Pol \_ 1} - {S}^{PEC} ,$$
$$and$$
$${S}_{Vt}^{CAL \_ Pol \_ 2} = {S}_{Vt}^{ANT \_ Pol \_ 2} - {S}^{PEC} ,$$
wherein S_{Vt}^{CAL_Pol_1} represents a first scattering sub-parameter extracted in a case that the third polarization direction of the single-channel test device is the first polarization direction of the antenna unit to be tested, S_{Vt}^{CAL_Pol_2} represents a second scattering sub-parameter extracted in a case that the single-channel test device is rotated by 90° to keep the third polarization direction in the second polarization direction of the antenna unit to be tested, S_{Vt}^{CAL_Pol_1} represents the target scattering parameter in the first polarization direction in the case that the control voltage is Vt, and S_{Vt}^{ANT_Pol_2} represents the target scattering parameter in the second polarization direction in the case that the control voltage is Vt.
